(19) United States
(12) Patent Application Publication
(10) Pub. No.: US 2022/0301476 A1
(43) Pub. Date: Sep. 22, 2022

(54) DISPLAY PANEL AND DISPLAY DEVICE

(71) Applicant: Shanghai AVIC OPTO Electronics Co., Ltd., Shanghai (CN)

(72) Inventors: Huijun JIN, Shanghai (CN); Lina SUN, Shanghai (CN)

(73) Assignee: Shanghai AVIC OPTO Electronics Co., Ltd., Shanghai (CN)

(21) Appl. No.: 17/806,090

(22) Filed: Jun. 9, 2022

(30) Foreign Application Priority Data
Dec. 29, 2021 (CN) 202111646513.6

(51) Int. Cl. G09G 3/20

(52) U.S. Cl. CPC G09G 3/20; G09G 2310/0286; G11C 19/28

(57) ABSTRACT

A display panel and a display device are provided. The display panel has a display area and a non-display area. The display panel includes: a gate drive circuit in the non-display area, where the gate drive circuit includes shift register circuits arranged along a first direction, and each of the shift register circuits includes a storage capacitor close to the display area; and gate line pads arranged between the gate drive circuit and the display area along the first direction. The storage capacitor includes a first sub-capacitor, a second sub-capacitor, a first connection electrode and a second connection electrode. The first connection electrode is connected with first sub-capacitor and second sub-capacitor, the second connection electrode is connected with second sub-capacitor and a gate line pad corresponding to the second sub-capacitor, and the second sub-capacitor is arranged between the first sub-capacitor and the gate line pad.

### CROSS REFERENCE OF RELATED APPLICATION

The present disclosure claims priority to Chinese Patent Application No. 202111646513.6, titled “DISPLAY PANEL AND DISPLAY DEVICE”, filed on Dec. 29, 2021 with the China National Intellectual Property Administration, which is incorporated herein by reference in its entirety.

### FIELD

The present disclosure relates to the field of display, and in particular to a display panel and a display device.

### BACKGROUND

Display devices such as liquid crystal displays (LCDs) or organic light-emitting diode displays (OLEDs) have the advantages of low radiation, small volume and low energy consumption, and thus are widely used in information products such as laptops, personal digital assistants (PDAs), flat panel TVs and mobile phones. A display device generally includes a gate drive circuit arranged in a frame area and multiple scanning lines arranged in a display area. The gate drive circuit includes shift register circuits deployed in multiple stages. One shift register circuit is connected with one scanning line, to provide a scanning signal for the scanning line. The gate drive circuit according to the conventional technology occupies a large area, which results in a wide frame of the display device.

### SUMMARY

One aspect of the present disclosure provides a display panel. The display panel includes a display area and a non-display area surrounding the display area. The display panel includes a gate drive circuit and multiple gate line pads. The gate drive circuit is arranged in the non-display area, and includes multiple shift register circuits arranged in sequence along a first direction. Each of the shift register circuits includes a storage capacitor close to the display area. The multiple gate line pads are arranged between the gate drive circuit and the display area in sequence along the first direction. The storage capacitor includes a first sub-capacitor, a second sub-capacitor, a first connection electrode and a second connection electrode. The first connection electrode is connected with the first sub-capacitor and the second sub-capacitor. The second connection electrode is connected with the second sub-capacitor and a gate line pad corresponding to the second sub-capacitor. The second sub-capacitor is arranged between the first sub-capacitor and the gate line pad.

Another aspect of the present disclosure provides a display device. The display device includes a display panel. The display panel includes a display area and a non-display area surrounding the display area. The display panel includes a gate drive circuit and multiple gate line pads. The gate drive circuit is arranged in the non-display area, and includes multiple shift register circuits arranged in sequence along a first direction. Each of the shift register circuits includes a storage capacitor close to the display area. The multiple gate line pads are arranged between the gate drive circuit and the display area in sequence along the first direction. The storage capacitor includes a first sub-capacitor, a second sub-capacitor, a first connection electrode and a second connection electrode. The first connection electrode is connected with the first sub-capacitor and the second sub-capacitor. The second connection electrode is connected with the second sub-capacitor and a gate line pad corresponding to the second sub-capacitor. The second sub-capacitor is arranged between the first sub-capacitor and the gate line pad.

Other aspects of the present disclosure can be understood in light of the description, the claims, and the drawings of the present disclosure.

### BRIEF DESCRIPTION OF THE DRAWINGS

In order to illustrate the embodiments of the present disclosure more clearly, the drawings to be used in the description of the embodiments are briefly described below. Apparently, the drawings in the following description show only some embodiments of the present disclosure, and other drawings may be conceived.

FIG. 1 is a schematic structural diagram of a display panel according to an embodiment of the present disclosure;

FIG. 2 is an equivalent circuit diagram of a shift register circuit according to an embodiment of the present disclosure;

FIG. 3 is a circuit layout of the shift register circuit shown in FIG. 2;

FIG. 4 is a schematic structural diagram of a storage capacitor according to an embodiment of the present disclosure;

FIG. 5 is a schematic structural diagram of a storage capacitor according to another embodiment of the present disclosure;

FIG. 6 is a schematic structural diagram of a storage capacitor according to yet another embodiment of the present disclosure;

FIG. 7 is a schematic structural diagram of a storage capacitor according to yet another embodiment of the present disclosure;

FIG. 8 is a schematic structural diagram of a storage capacitor according to yet another embodiment of the present disclosure;

FIG. 9 is a schematic structural diagram of a storage capacitor according to yet another embodiment of the present disclosure;

FIG. 10 is a schematic structural diagram of a display panel according to another embodiment of the present disclosure;

FIG. 11 is a schematic structural diagram of a storage capacitor according to yet another embodiment of the present disclosure;

FIG. 12 is a schematic structural diagram of a display panel according to yet another embodiment of the present disclosure;

FIG. 13 is a schematic structural diagram of a display panel according to yet another embodiment of the present disclosure;

FIG. 14 is a schematic structural diagram of a display panel according to yet another embodiment of the present disclosure;

FIG. 15 is a schematic structural diagram of a display panel according to yet another embodiment of the present disclosure;

FIG. 16 is a schematic structural diagram of a display panel according to yet another embodiment of the present disclosure;

FIG. 17 is a schematic structural diagram of a display panel according to yet another embodiment of the present disclosure;

FIG. 18 is a schematic structural diagram of a storage capacitor according to yet another embodiment of the present disclosure;

FIG. 19 is a schematic structural diagram of a storage capacitor according to yet another embodiment of the present disclosure; and

FIG. 20 is a schematic structural diagram of a display device according to an embodiment of the present disclosure.

### DETAILED DESCRIPTION

The embodiments of the present disclosure are described clearly and completely in conjunction with the drawings in the embodiments of the present disclosure hereinafter. It is apparent that the described embodiments are only some embodiments of the present disclosure, rather than all embodiments.

As described in the background section, display devices such as liquid crystal displays (LCDs) or organic light-emitting diode displays (OLEDs) have the advantages of low radiation, small volume and low energy consumption, and thus are widely used in information products such as laptops, personal digital assistants (PDAs), flat panel TVs and mobile phones. The display device includes a gate drive circuit arranged in a frame area and multiple scanning lines arranged in a display area. The gate drive circuit includes shift register circuits deployed in multiple stages. One shift register circuit is connected with one scanning line, to provide a scanning signal for the scanning line. The gate drive circuit according to the conventional technology occupies a large area, which results in a wide frame of the display device.

In view of this, a display panel and a display device are provided according to embodiments of the present disclosure, which can effectively solve the problem in the conventional technology, make full use of a gap area between a gate line pad and the gate drive circuit by arranging a second sub-capacitor of a storage capacitor in the gap area, and reduce a width of the first sub-capacitor while ensuring an expected capacity of the storage capacitor, and the display device conforms to the design trend of narrow frame.

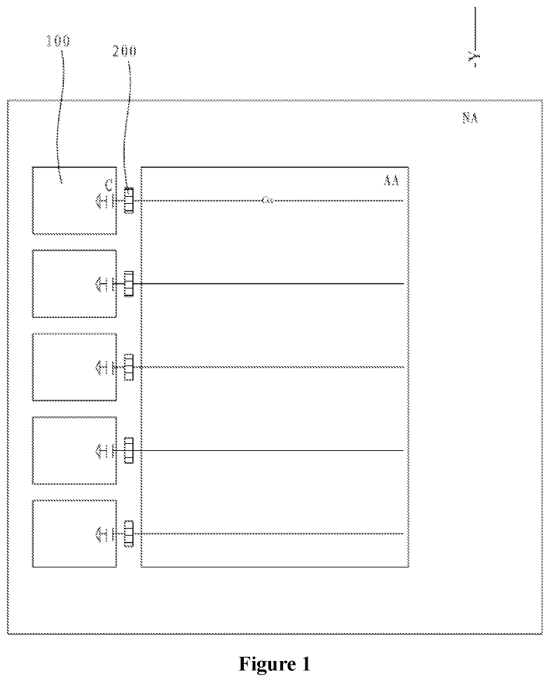

To achieve the above objectives, the following embodiments of the present disclosure are described in detail in conjunction with FIGS. 1 to 20.

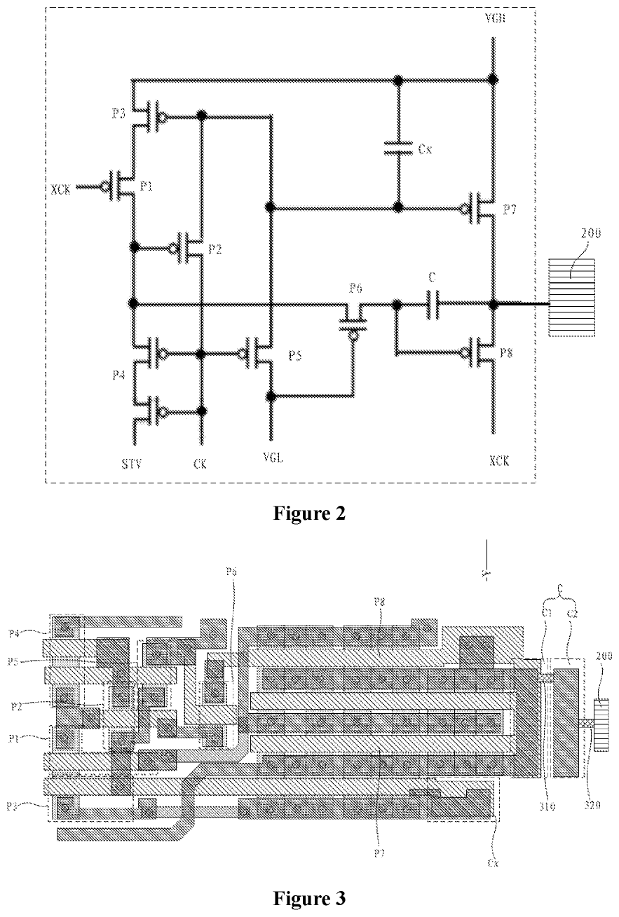

FIG. 1 is a schematic structural diagram of a display panel according to an embodiment of the present disclosure, FIG. 2 is an equivalent circuit diagram of a shift register circuit according to an embodiment of the present disclosure, and FIG. 3 is a circuit layout of the shift register circuit shown in FIG. 2. It should be noted that the shift register circuit shown in FIGS. 2 and 3 according to the embodiment of the present disclosure represents one exemplary circuit structure applicable for the present disclosure, and is merely for the purpose of illustrating embodiments according to the present disclosure. In another embodiment of the present disclosure, the shift register circuit may be of other types.

The display panel according to the embodiment of the present disclosure includes a display area AA and a non-display area NA surrounding the display area AA.

The display panel includes a gate drive circuit and multiple gate line pads 200. The gate drive circuit is arranged in the non-display area NA. The gate drive circuit includes multiple shift register circuits 100 arranged in sequence along a first direction Y. Each of the shift register circuits 100 includes a storage capacitor C close to the display area AA. The storage capacitor C is electrically connected with a gate line pad 200.

The multiple gate line pads 200 are arranged between the gate drive circuit and the display area AA in sequence along the first direction Y. The gate line pad 200 is configured to transmit a scanning signal to a scanning line Gx.

The storage capacitor C includes a first sub-capacitor C1, a second sub-capacitor C2, a first connection electrode 310 and a second connection electrode 320. The first connection electrode 310 is connected with the first sub-capacitor C1 and the second sub-capacitor C2. The second connection electrode 320 is connected with the second sub-capacitor C2 and a gate line pad 200 corresponding to the second sub-capacitor C2. The second sub-capacitor C2 is arranged between the first sub-capacitor C1 and the gate line pad 200.

As shown in FIGS. 2 and 3, the shift register circuit 100 according to the embodiment of the present disclosure includes a first transistor P1, a second transistor P2, a third transistor P3, a fourth transistor P4, a fifth transistor P5, a sixth transistor P6, a seventh transistor P7, an eighth transistor P8, an auxiliary capacitor Cx and the storage capacitor C. The shift register circuit 100 further includes a start signal line STV, a clock signal line CK, a clock signal line XCK, a low-level voltage signal line VGL and a high-level voltage signal line VGH that are each connected with corresponding transistors. An operation process of the shift register circuit 100 is the same as that of the conventional technology, which is not described in detail in the present disclosure. It should be noted that the transistors in the shift register circuit 100 according to the embodiment of the present disclosure may be P-type or N-type transistors. In practices, the type of the transistors depends on signals transmitted on the signal lines and a level signal required for the display area AA, which is not limited in the present disclosure.

It can be understood that the storage capacitor C according to the embodiment of the present disclosure is normally arranged in an edge area of the shift register circuit 100 close to the gate line pad 200. The storage capacitor C is connected with the gate line pad 200 via the second connection electrode 320, to maintain a potential at the gate line pad 200. The storage capacitor C according to the embodiment of the present disclosure includes a first sub-capacitor C1 and a second sub-capacitor C2. The first sub-capacitor C1 is connected with the second sub-capacitor C2 via the first connection electrode 310. In one embodiment, the first sub-capacitor C1 is connected in parallel with the second sub-capacitor C2. In the embodiment of the present disclosure, a gap area between the gate line pad 200 and the gate drive circuit is fully utilized by arranging the second sub-capacitor C2 of the storage capacitor C in the gap area, which can reduce a width of the first sub-capacitor C1 while ensuring an expected capacity of the storage capacitor C, and the display device conforms to the design trend of narrow frame.

In an embodiment of the present disclosure, the first sub-capacitor, the second sub-capacitor, and the first connection electrode connected with the first sub-capacitor and the second sub-capacitor according to the embodiment of the present disclosure may form various shapes to meet different line layouts. The shapes of the storage capacitor according to the embodiments of the present disclosure are described in detail in combination with the drawings hereinafter.

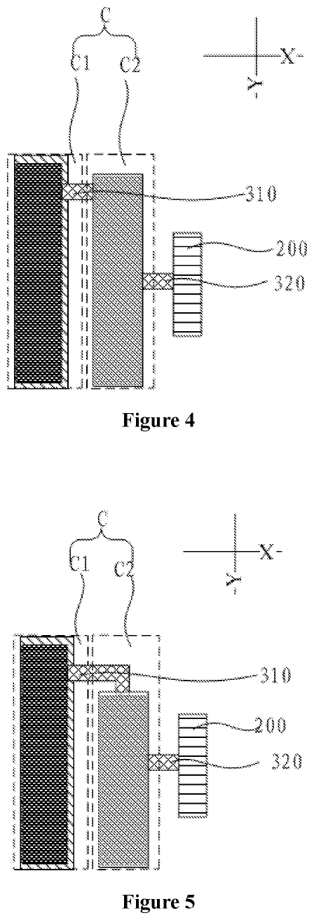

Reference is made to FIG. 4, which is a schematic structural diagram of a storage capacitor according to an embodiment of the present disclosure. The first connection electrode 310 according to the embodiment of the present disclosure is arranged between the first sub-capacitor C1 and the second sub-capacitor C2. The first connection electrode 310 is arranged within a coverage range of at least one of the first sub-capacitor C1 and the second sub-capacitor C2 in a second direction X. The second direction X is perpendicular to the first direction Y. The second direction X may be an extension direction of the scanning line Gx.

It may be understood that the first connection electrode 310 according to the embodiment of the present disclosure is arranged in an area between the first sub-capacitor C1 and the second sub-capacitor C2. In an orthographic projection of the storage capacitor C on a plane parallel to a plane where the display panel is arranged, the first connection electrode 310 is arranged within the coverage range of at least one of the first sub-capacitor C1 and the second sub-capacitor C2 in the second direction X, (that is, the first connection electrode 310 is overlapped with at least one of the first sub-capacitor C1 and the second sub-capacitor C2).

As shown in FIG. 4, in the orthographic projection of the storage capacitor C on the plane parallel to the plane where the display panel is arranged, the first connection electrode 310 is arranged within the coverage range of the first sub-capacitor C1 and the second sub-capacitor C2 in the second direction X. In the orthographic projection of the storage capacitor C on the plane parallel to the plane where the display panel is arranged, the first sub-capacitor C1, the second sub-capacitor C2 and the first connection electrode 310 together form a shape of character “H”. Alternatively, reference is made to FIG. 5, which is a schematic structural diagram of a storage capacitor according to another embodiment of the present disclosure. In the orthographic projection of the storage capacitor C on the plane parallel to the plane where the display panel is arranged, the first connection electrode 310 is arranged within a coverage range of the first sub-capacitor C1 and is not overlapped with the second sub-capacitor C2 in the second direction X. In the orthographic projection of the storage capacitor C on the plane parallel to the plane where the display panel is arranged, the first sub-capacitor C1, the second sub-capacitor C2 and the first connection electrode 310 together form a shape of character “h”.

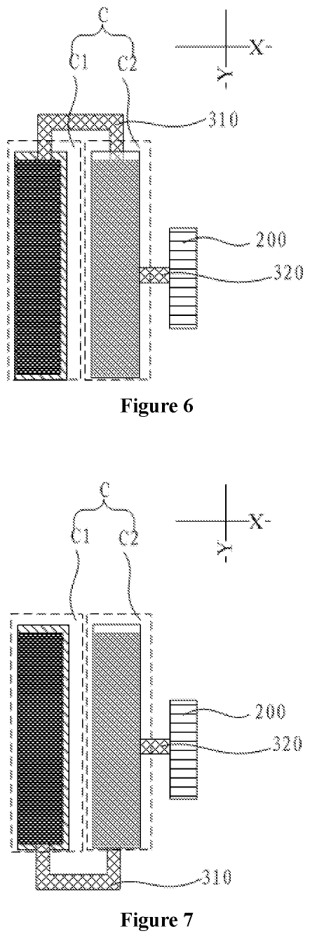

Reference is made to FIG. 6, which is a schematic structural diagram of a storage capacitor according to another embodiment of the present disclosure. The first connection electrode 310 according to the embodiment of the present disclosure is arranged on a same side as the first sub-capacitor C1 and the second sub-capacitor C2 in the first direction Y. In the orthographic projection of the storage capacitor C on the plane parallel to the plane where the display panel is arranged, the first connection electrode 310 overlaps with neither the first sub-capacitor C1 nor the second sub-capacitor C2 in the second direction X. The second direction X is perpendicular to the first direction Y.

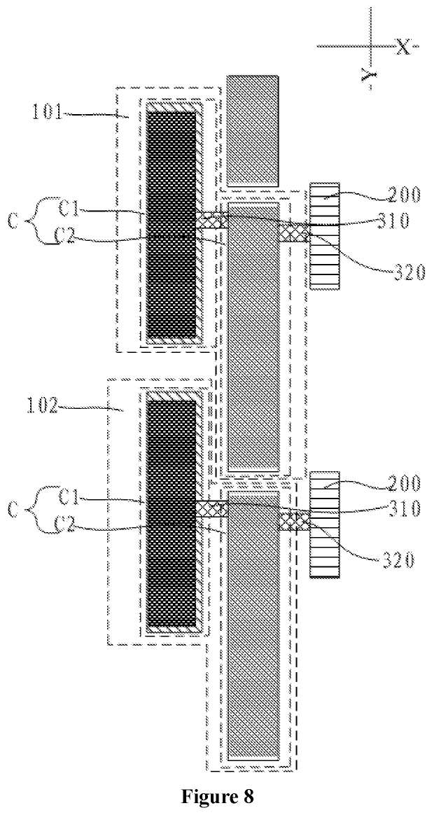

As shown in FIG. 6, in the orthographic projection of the storage capacitor C on the plane parallel to the plane where the display panel is arranged, the first connection electrode 310 is overlapped with neither the first sub-capacitor C1 nor the second sub-capacitor C2 in the second direction X, and the first sub-capacitor C1, the second sub-capacitor C2 and the first connection electrode 310 may form an inverted U-shape collectively. Alternatively, reference is made to FIG. 7, which is a schematic structural diagram of a storage capacitor according to another embodiment of the present disclosure. In the orthographic projection of the storage capacitor C on the plane parallel to the plane where the display panel is arranged, the first connection electrode 310 is overlapped with neither the first sub-capacitor C1 nor the second sub-capacitor C2 in the second direction X, and the first sub-capacitor C1, and the second sub-capacitor C2 and the first connection electrode 310 may form a U-shape collectively.

Reference is made to FIG. 8, which is a schematic structural diagram of a storage capacitor according to another embodiment of the present disclosure. In the orthographic projection of the storage capacitor C on the plane parallel to the plane where the display panel is arranged, a second sub-capacitor C2 of a shift register circuit 101 among the shift register circuits 100 extends along the first direction Y, and is overlapped with a first sub-capacitor C1 of an adjacent shift register circuit 102 in the second direction X. The second direction X is perpendicular to the first direction Y.

In an embodiment of the present disclosure, the shift register circuit 100 according to the present disclosure may be arranged opposite to the gate line pad 200 connected with the shift register circuit 100 in the second direction X. As shown in FIG. 8, the shift register circuit 100 is arranged opposite to the gate line pad 200 connected with the shift register circuit 100, that is, in orthographic projections of the shift register circuit 100 and the gate line pad 200 on the plane parallel to the plane where the display panel is arranged, the gate line pad 200 is arranged within a range of the shift register circuit 100 in the second direction.

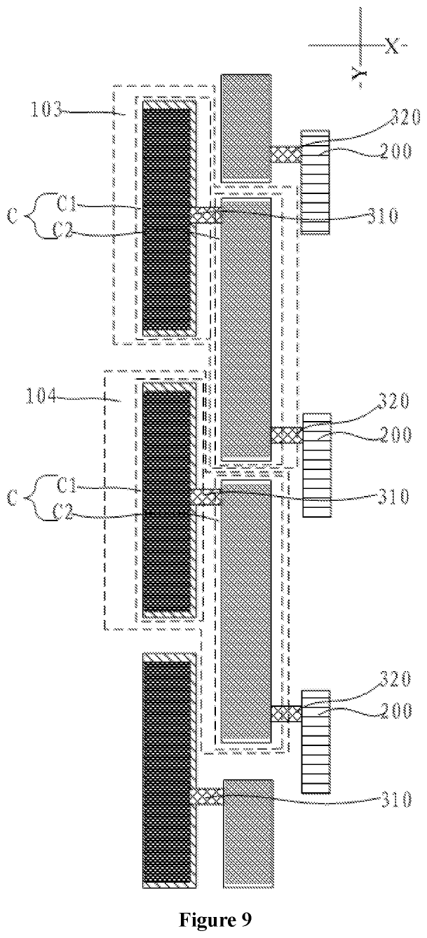

Some embodiments in which the shift register circuit is arranged opposite to the gate line pad corresponding to the shift register circuit in the second direction, the shift register circuit and the gate line pad according to the embodiment of the present disclosure may be arranged in a staggered manner. Reference is made to FIG. 9, which is a schematic structural diagram of a storage capacitor according to another embodiment of the present disclosure. In the orthographic projection of the storage capacitor C on the plane parallel to the plane where the display panel is arranged, a first sub-capacitor C1 of one shift register circuit 104 among the shift register circuits 100 is overlapped with a gate line pad 200 connected with an adjacent shift register circuit 103 in the second direction X. The second direction X is perpendicular to the first direction Y. That is, in the wiring solution shown in FIG. 9, a position of the gate line pad 200 relative to the scanning line Gx is unchanged, and a position of the gate drive circuit relative to the gate line pad 200 is moved up or down along the first direction Y for a distance, and there is more wiring space at one end of the gate drive circuit 200 in the first direction Y.

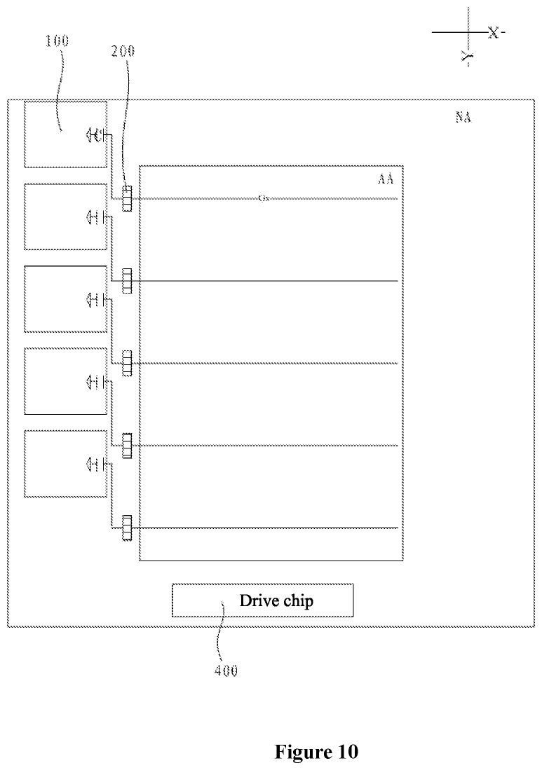

In an embodiment, the gate drive circuit according to the embodiment of the present disclosure may be moved up along the first direction for a distance. Reference is made to FIG. 10, which is a schematic structural diagram of a display panel according to another embodiment of the present disclosure. The non-display area NA of the display panel includes a drive chip 400. The gate drive circuit according to the embodiment of the present disclosure is moved away from the drive chip 400 in the first direction Y for a distance and the shift register circuit 100 is staggered to the gate line pad 200 connected with the shift register circuit 100 in the first direction Y, and there is more wiring space at a side of the gate drive circuit close to the drive chip 400.

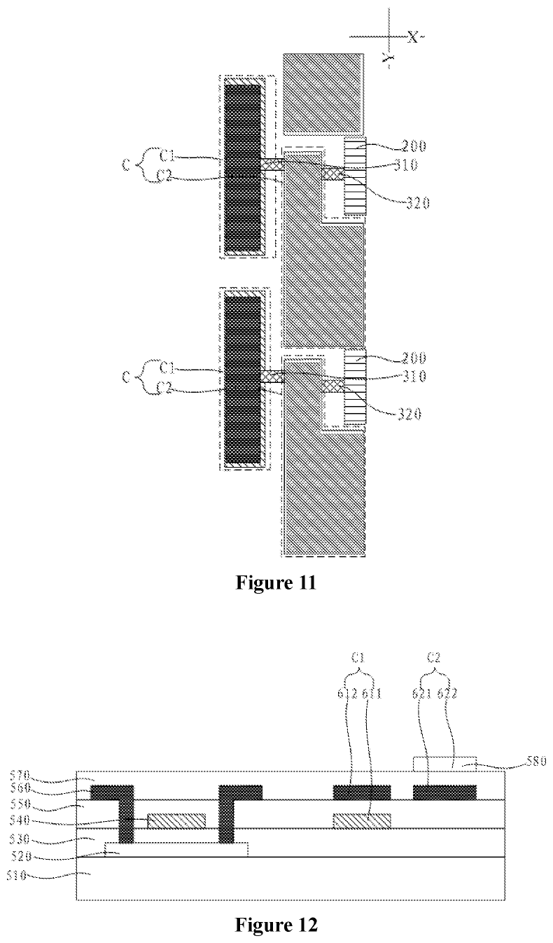

Further, the second sub-capacitor according to the embodiment of the present disclosure may extend to a gap between two adjacent gate line pads, to flexibly control capacity of the storage capacitor. Reference is made to FIG. 11, which is a schematic structural diagram of a storage capacitor according to yet another embodiment of the present disclosure. The second sub-capacitor C2 extends to a gap between the adjacent gate line pads 200 along the second direction X, to flexibly control capacity of the storage capacitor C.

It should be noted that the shapes of the storage capacitor shown in the above embodiments are merely some exemplary applicable shapes according to the present disclosure. In another embodiment of the present disclosure, the storage capacitor may be in other shapes.

Reference is made to FIG. 12, which is a schematic structural diagram of a display panel according to yet another embodiment of the present disclosure. The display panel according to the embodiment of the present disclosure includes a substrate 510, a semiconductor layer 520, a gate insulating layer 530, a first metal layer 540, a first insulating layer 550, a second metal layer 560, a second insulating layer 570 and a conductive film layer 580. The semiconductor layer 520 is arranged on a side of the substrate 510, and includes an active region configured for forming a transistor. The gate insulating layer 530 is arranged on a side of the semiconductor layer 520 away from the substrate 510. As used herein, expression such as “on a side of” or “at a side of” does not necessitate contact between the elements. The gate insulating layer 530, arranged on or at a side of the semiconductor layer 520 away from the substrate 510, may be in contact with the semiconductor layer or may be spaced from the semiconductor layer. The first metal layer 540 is arranged on a side of the gate insulating layer 530 away from the substrate 510, and includes a gate configured for forming the transistor. The first insulating layer 550 is arranged on a side of the first metal layer 540. The second metal layer 560 is arranged on a side of the first insulating layer 550 away from the first metal layer 540, and includes a source and a drain that form the transistor. The second insulating layer 570 is arranged on a side of the second metal layer 560 away from the first metal layer 540. The conductive film layer 580 is arranged on a side of the second insulating layer 570 away from the first metal layer 540. At least two of the first metal layer 540, the second metal layer 560 and the conductive film layer 580 include electrode plates of the first sub-capacitor C1 and the second sub-capacitor C2.

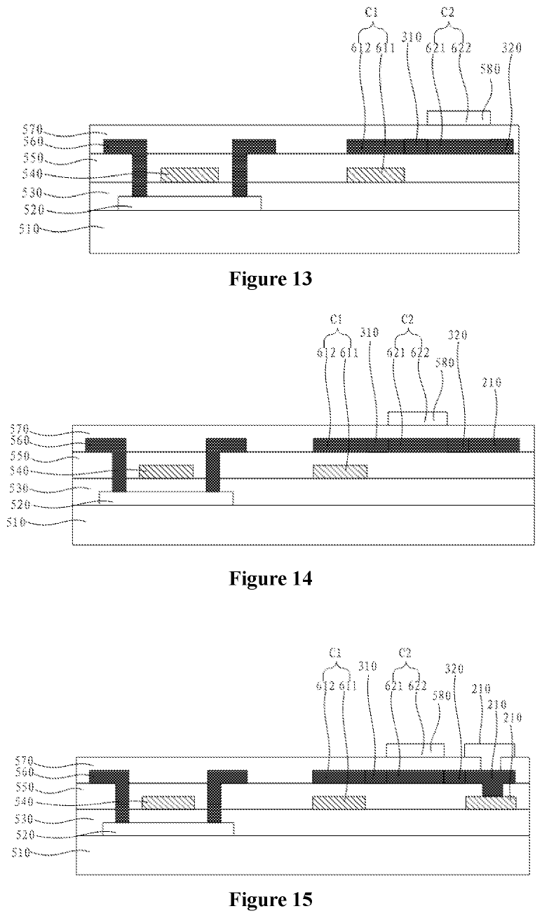

Reference is made to FIG. 13, which is a schematic structural diagram of a display panel according to yet another embodiment of the present disclosure. The first metal layer 540 includes a first electrode plate 611 of the first sub-capacitor C1. The second metal layer 560 includes a second electrode plate 612 of the first sub-capacitor C1 and a first electrode plate 621 of the second sub-capacitor C2. The conductive film layer 580 includes a second electrode plate 622 of the second sub-capacitor C2. The first connection electrode 310 is connected with the second electrode plate 612 of the first sub-capacitor C1 and the first electrode plate 621 of the second sub-capacitor C2. The second connection electrode 320 is connected with the first electrode plate 621 of the second sub-capacitor C2 and the gate line pad 200. It can be understood that the first sub-capacitor C1 is connected in parallel with the second sub-capacitor C2 according to the embodiment of the present disclosure, and the capacity of the storage capacitor C can meet the expected requirements.

As shown in FIG. 13, the second metal layer 560 and at least one of the first connection electrode 310 and the second connection electrode 320 according to the present disclosure are arranged in a same layer. The first connection electrode 310 and the second connection electrode 320 are formed with a material layer already existing in the display panel, i.e., no additional metal layer is need for forming the first electrical connection electrode and the second connection electrode, saving resources and further reducing difficulty of manufacturing process.

Reference is made to FIG. 14, which is a schematic structural diagram of a display panel according to another embodiment of the present disclosure. The gate line pad includes at least one layer of sub pad 210. The second metal layer 560 includes the sub pad 210 and the second connection electrode 320 connected with the sub pad 210. Furthermore, the sub pad 210 can be directly connected with the second connection electrode 320, eliminating process of forming via-hole connection and reducing the difficulty of manufacturing process. In addition, the gate line pad 200 may be made into a structure of stacked sub pads 210, which can reduce impedance of the gate line pad 200 and improve signal transmission performance.

Reference is made to FIG. 15, which is a schematic structural diagram of a display panel according to another embodiment of the present disclosure. At least one of the first metal layer 540 and the conductive film layer 580 includes the sub pad 210. The sub pad 210 in the first metal layer 540, the sub pad 210 in the second metal layer 560 and the sub pad 210 in the conductive film layer 580 may be connected with each other via a via-hole to reduce the impedance of the gate line pad 200.

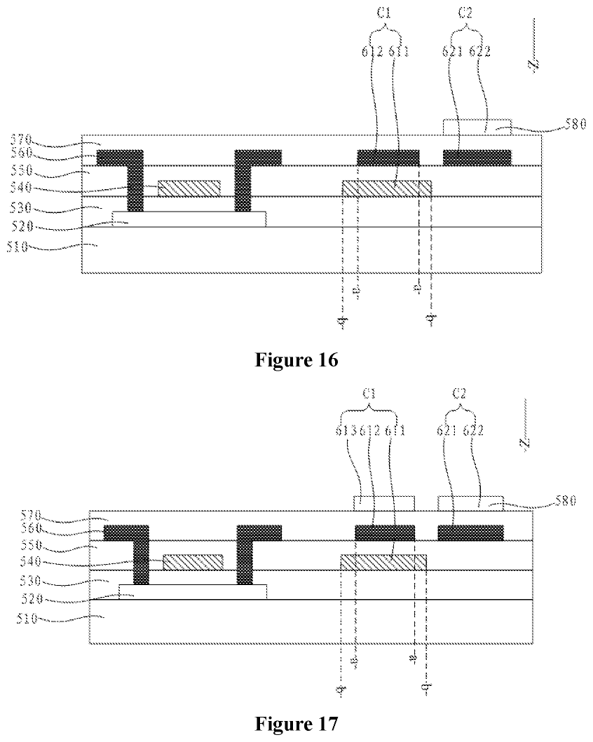

Reference is made to FIG. 16, which is a schematic structural diagram of a display panel according to yet another embodiment of the present disclosure. In a direction Z from the first metal layer 540 to the second metal layer 560, an orthographic projection “a” of at least one edge of the second electrode plate 612 of the first sub-capacitor C1 on the second insulating layer 550 is within a range of an orthographic projection “b” of an edge, at the same side, of the first electrode plate 611 of the first sub-capacitor C1 on the second insulating layer 550. It can be understood that the first electrode plate 611 of the first sub-capacitor C1 is arranged in the first metal layer 540. After the first electrode plate 611 of the first sub-capacitor C1 is manufactured, it is prone to generate static electricity between the first electrode plate 611 of the first sub-capacitor C1 and other electrode structures that is arranged in a same layer as the first electrode plate 611 in subsequent process of manufacturing other film layers such as the second insulating layer 550 and the second metal layer 560. The static electricity may cause breakdown of the second insulating layer 550 at the edge of the first electrode plate 611 of the first sub-capacitor C1, and metal material of the second metal layer 560 is shorted to the first electrode plate 611 of the first sub-capacitor C1 at the position of the breakdown when the second metal layer 560 is manufactured. Therefore, in the embodiment of the present disclosure, the second electrode plate 612 of the first sub-capacitor C1 is retreated relative to the edge of the first electrode plate 611, to avoid short circuit between the first electrode plate 611 and the second electrode plate 612.

In an embodiment of the present disclosure, a distance between “b” and “a” according to the present disclosure is greater than or equal to 1 micron, and a distance between the first electrode plate 611 and the second electrode plate 612 of the first sub-capacitor C1 is adequate to avoid short circuit.

For more flexible adjustment of the capacity of the storage capacitor, the conductive film layer according to the present disclosure may further include an electrode plate of the first sub-capacitor. Reference is made to FIG. 17, which is a schematic structural diagram of a display panel according to another embodiment of the present disclosure. The first sub-capacitor C1 according to the embodiment of the present disclosure further includes a third electrode plate 613. The conductive film layer 580 includes the third electrode plate 613 of the first sub-capacitor C1. The third electrode plate 613 of the first sub-capacitor C1 is connected with the second electrode plate 622 of the second sub-capacitor C2. Therefore, the capacity of the storage capacitor can be adjusted more flexibly, and the storage capacitor is suitable for various types of shift register circuits, i.e., having extended application scope.

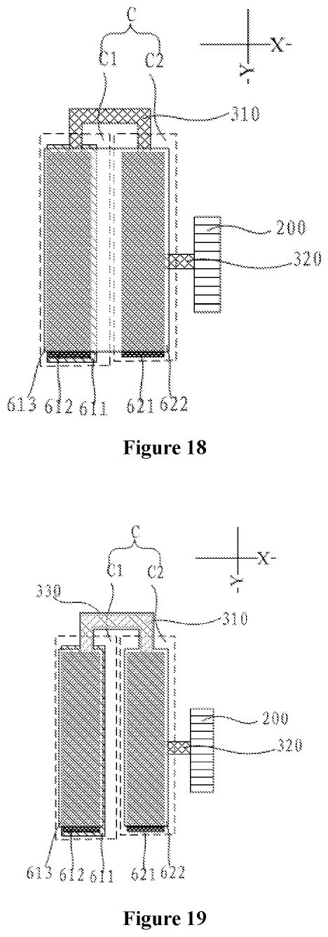

In an embodiment of the present disclosure, the third electrode plate of the first sub-capacitor may be reused as the second electrode plate of the second sub-capacitor according to the present disclosure. In this case, the third electrode plate of the first sub-capacitor is block-shaped, and is overlapped with both the second electrode plate of the first sub-capacitor and the first electrode plate of the second sub-capacitor. Reference is made to FIG. 18, which is a schematic structural diagram of a storage capacitor according to another embodiment of the present disclosure. The third electrode plate 613 of the first sub-capacitor C1 is reused as the second electrode plate 622 of the second sub-capacitor C2.

Alternatively, the third electrode plate of the first sub-capacitor and the second electrode plate of the second sub-capacitor according to the embodiment of the present disclosure are two independent electrode plates, and the two electrode plates are connected with each other via an auxiliary connection electrode. Reference is made to FIG. 19, which is a schematic structural diagram of a storage capacitor according to another embodiment of the present disclosure. The storage capacitor C includes an auxiliary connection electrode 330. The auxiliary connection electrode 330 is connected with the third electrode plate 613 of the first sub-capacitor C1 and the second electrode plate 622 of the second sub-capacitor C2. Further, in a direction from the first metal layer to the second metal layer, the auxiliary connection electrode 330 is overlapped with the first connection electrode 310. That is, the first connection electrode 310 and the auxiliary connecting electrode 330 form a capacitor, to further improve the flexibility in capacity adjustment of the storage capacitor C. The conductive film layer according to the embodiment of the present disclosure includes the auxiliary connection electrode 330, to reduce the difficulty of the manufacturing process.

Accordingly, a display device is further provided according to the present disclosure. The display device includes the display panel according to any one of the above embodiments.

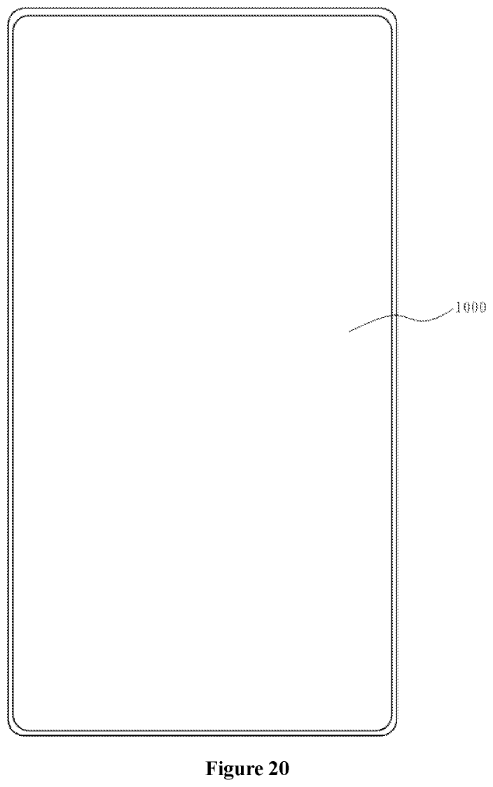

Reference is made to FIG. 20, which is a schematic structural diagram of a display device according to an embodiment of the present disclosure. A display device 1000 according to the embodiment of the present disclosure may be a mobile terminal. The display device 1000 includes the display panel according to any one of the above embodiments.

It should be noted that the display device according to the embodiment of the present disclosure may alternatively be a notebook, a tablet computer, a computer, a wearable device and the like, which is not limited in the present disclosure.

A display panel and a display device are provided according to the embodiments of the present disclosure. The display panel includes a display area and a non-display area surrounding the display area. The display panel includes a gate drive circuit and multiple gate line pads. The gate drive circuit is arranged in the non-display area, and includes multiple shift register circuits arranged in sequence along a first direction. Each of the shift register circuits includes a storage capacitor close to the display area. The multiple gate line pads are arranged between the gate drive circuit and the display area in sequence along the first direction. The storage capacitor includes a first sub-capacitor, a second sub-capacitor, a first connection electrode and a second connection electrode. The first connection electrode is connected with the first sub-capacitor and the second sub-capacitor. The second connection electrode is connected with the second sub-capacitor and a gate line pad corresponding to the second sub-capacitor. The second sub-capacitor is arranged between the first sub-capacitor and the gate line pad.

It can be seen from the above that in the embodiments of the present disclosure, the storage capacitor includes the first sub-capacitor and the second sub-capacitor. According to the embodiments of the present disclosure, a gap area between the gate line pad and the gate drive circuit is fully utilized by arranging the second sub-capacitor of the storage capacitor in the gap area, which can reduce a width of the first sub-capacitor while ensuring an expected capacity of the storage capacitor, and the display device conforms to the design trend of narrow frame.

What is claimed is:

1. A display panel comprising a display area and a non-display area surrounding the display area, wherein the display panel comprises:
a gate drive circuit arranged in the non-display area, wherein the gate drive circuit comprises a plurality of shift register circuits arranged in sequence along a first direction, and each of the shift register circuits comprises a storage capacitor close to the display area; and
a plurality of gate line pads arranged between the gate drive circuit and the display area in sequence along the first direction, wherein
the storage capacitor comprises a first sub-capacitor, a second sub-capacitor, a first connection electrode and a second connection electrode, the first connection electrode is connected with the first sub-capacitor and the second sub-capacitor, the second connection electrode is connected with the second sub-capacitor and a gate line pad corresponding to the second sub-capacitor, and the second sub-capacitor is arranged between the first sub-capacitor and the gate line pad.

2. The display panel according to claim 1, wherein
the first connection electrode is arranged between the first sub-capacitor and the second sub-capacitor; and
the first connection electrode is arranged within a coverage range of at least one of the first sub-capacitor and the second sub-capacitor in a second direction, wherein the second direction is perpendicular to the first direction.

3. The display panel according to claim 1, wherein
the first connection electrode is arranged on a same side of the first sub-capacitor and the second sub-capacitor in the first direction; and
in an orthographic projection of the storage capacitor on a plane parallel to a plane where the display panel is arranged, the first connection electrode is overlapped with neither the first sub-capacitor nor the second sub-capacitor in a second direction, wherein the second direction is perpendicular to the first direction.

4. The display panel according to claim 1, wherein
in an orthographic projection of the storage capacitor on a plane parallel to a plane where the display panel is arranged, a second sub-capacitor of any one of the shift register circuits extends along the first direction and is overlapped with a first sub-capacitor of an adjacent shift register circuit in a second direction, wherein the second direction is perpendicular to the first direction.

5. The display panel according to claim 1, wherein
in an orthographic projection of the storage capacitor on a plane parallel to a plane where the display panel is arranged, a first sub-capacitor of any one of the shift register circuits is overlapped with a gate line pad connected to an adjacent shift register circuit in a second direction, wherein the second direction is perpendicular to the first direction.

6. The display panel according to claim 1, further comprising:
a first metal layer;
a first insulating layer arranged at a side of the first metal layer;
a second metal layer arranged at a side of the first insulating layer away from the first metal layer;
a second insulating layer arranged at a side of the second metal layer away from the first metal layer; and
a conductive film layer arranged at a side of the second insulating layer away from the first metal layer, wherein
at least two of the first metal layer, the second metal layer and the conductive film layer comprises electrode plates of the first sub-capacitor and the second sub-capacitor.

7. The display panel according to claim 6, wherein
the first metal layer comprises a first electrode plate of the first sub-capacitor, the second metal layer comprises a second electrode plate of the first sub-capacitor and a first electrode plate of the second sub-capacitor, and the conductive film layer comprises a second electrode plate of the second sub-capacitor, wherein
the first connection electrode is connected with the second electrode plate of the first sub-capacitor and the first electrode plate of the second sub-capacitor, and the second connection electrode is connected with the first electrode plate of the second sub-capacitor and the gate line pad.

8. The display panel according to claim 7, wherein
the second metal layer and at least one of the first connection electrode and the second connection electrode are arranged in a same layer.

9. The display panel according to claim 7, wherein
the gate line pad comprises at least one layer of sub pad, and the second metal layer comprises the sub pad and the second connection electrode connected with the sub pad.

10. The display panel according to claim 7, wherein
at least one of the first metal layer and the conductive film layer comprises one layer of sub pad.

11. The display panel according to claim 7, wherein
in a direction from the first metal layer to the second metal layer, an orthographic projection a of at least one edge of the second electrode plate of the first sub-capacitor on the second insulating layer is arranged within a range of an orthographic projection b of an edge of the first electrode plate of the first sub-capacitor on the second insulating layer, wherein the at least one edge of the second electrode plate and the edge of the first electrode plate are on a same side.

12. The display panel according to claim 11, wherein a distance between b and a is greater than or equal to 1 micron.

13. The display panel according to claim 7, wherein
the first sub-capacitor further comprises a third electrode plate, wherein
the conductive film layer comprises the third electrode plate of the first sub-capacitor, and the third electrode plate of the first sub-capacitor is connected with the second electrode plate of the second sub-capacitor.

14. The display panel according to claim 13, wherein
the third electrode plate of the first sub-capacitor is reused as the second electrode plate of the second sub-capacitor.

15. The display panel according to claim 13, wherein
the storage capacitor comprises an auxiliary connection electrode, and the auxiliary connection electrode is connected with the third electrode plate of the first sub-capacitor and the second electrode plate of the second sub-capacitor.

16. The display panel according to claim 15, wherein
in a direction from the first metal layer to the second metal layer, the auxiliary connection electrode is overlapped with the first connection electrode.

17. The display panel according to claim 15, wherein
the conductive film layer comprises the auxiliary connection electrode.

18. A display device comprising a display panel, wherein the display panel comprises a display area and a non-display area surrounding the display area, and the display panel further comprises:
a gate drive circuit arranged in the non-display area, wherein the gate drive circuit comprises a plurality of shift register circuits arranged in sequence along a first direction, and each of the shift register circuits comprises a storage capacitor close to the display area; and
a plurality of gate line pads arranged between the gate drive circuit and the display area in sequence along the first direction, wherein
the storage capacitor comprises a first sub-capacitor, a second sub-capacitor, a first connection electrode and a second connection electrode, the first connection electrode is connected with the first sub-capacitor and the second sub-capacitor, the second connection electrode is connected with the second sub-capacitor and a gate line pad corresponding to the second sub-capacitor, and the second sub-capacitor is arranged between the first sub-capacitor and the gate line pad.
